(19) United States
(12) Patent Application Publication
(10) Pub. No.: US 2016/0037651 A1
(43) Pub. Date: Feb. 4, 2016

(54) PROCESS FOR PRODUCING THREE-DIMENSIONAL CONDUCTIVE PATTERN STRUCTURE, AND MATERIAL FOR THREE-DIMENSIONAL MOLDING FOR USE THEREIN

(71) Applicant: SEIREN CO., LTD., Fukui (JP)

(72) Inventors: Takashi UESUGI, Fukui (JP); Kazuhisa TSUJIMOTO, Fukui (JP)

(73) Assignee: SEIREN CO., LTD., Fukui (JP)

(21) Appl. No.: 14/783,136

(22) PCT Filed: Apr. 10, 2014
(86) PCT No.: PCT/JP2014/060437

§ 371 Date: Oct. 8, 2015

(30) Foreign Application Priority Data
Apr. 12, 2013 (JP) 2013-083774

(51) Int. Cl. H05K 3/18; H05K 3/00; C23C 18/30; C23C 18/16; C23C 18/20

(52) U.S. Cl. CPC H05K 3/182; C23C 18/1653; C23C 18/208; C23C 18/30; H05K 3/0014

(57) ABSTRACT

[Problem] To provide: a material which is for three-dimensional molding and on which a conductive pattern that exhibits excellent adhesiveness even after the three-dimensional molding can be formed; and a process for producing a three-dimensional conductive pattern structure, said process using this material for three-dimensional molding and necessitating no special apparatus. [Solution] This three-dimensional conductive pattern structure is produced by: using a material which is for three-dimensional molding and which has, in at least a part thereof, a surface made of a polyimide resin; conducting, in a surface portion (1) made of a polyimide resin, the formation of a modified pattern and then the adsorption and reduction of metal ions to form a material which is provided with a pattern (2) having a plating-catalyzing activity; and subjecting the material which is provided with the pattern (2) to three-dimensional molding and electroless plating successively.

### TECHNICAL FIELD

The present invention relates to a molding material, process for producing the same and a three-dimensional conductive pattern structure.

In more detail, the present invention relates to a molding material which can be a three-dimensional structure by molding, that is, a molding material on which a conductive pattern can be formed over several flat or curved surfaces thereof, and a process for producing the same.

In addition, the present invention relates to a three-dimensional conductive pattern structure made of said molding material.

### BACKGROUND ART

In the field of electronic components, decorating items or the like, resin materials with a metal film conductive pattern formed thereon have been used from many years ago. Typical examples thereof include a flexible printed-wiring board wherein a metal film circuit pattern is formed on the surface of a resin film.

In recent years, in addition, there is a demand for a three-dimensional conductive pattern structure wherein a conductive pattern such as a metal film circuit or the like is formed on the surface of a resin material that is three-dimensionally molded.

As one of the methods for forming a circuit pattern on the surface of a three-dimensionally molded resin article, Patent Document 1 discloses a method wherein, after molding a resin article, a metal film is formed by plating or the like on the whole surface of the article, and then, a pattern is formed by a photolithography-etching processing or a laser processing.

Another method is disclosed in Patent Document 2 wherein a circuit pattern is formed by coating a conductive paste containing conductor metal powders and a binder such as a thermosetting resin as main raw materials on the surface of a resin molded article which is preliminary masked, and then a metal film is formed by plating.

Patent Document 3 discloses a method wherein a circuit pattern of a metal film is formed preliminary, and then a molding process is carried out.

Yet another method can be proposed wherein, after a molding material which is pattern-printed using a plating catalyst ink containing a binder resin is three-dimensionally molded, electroless plating is carried out with said three-dimensional molded article.

### PRIOR ART DOCUMENTS

### Patent Document

Patent Document 1: Jpn. Pat. Laid-Open Publication No. H06-164105

Patent Document 2: Jpn. Pat. Laid-Open Publication No. 2009-164340

Patent Document 3: Jpn. Pat. Laid-Open Publication No. 2008-192789

### DISCLOSURE OF THE INVENTION

### Problems to be Solved by the Invention

However, the method disclosed in Patent Document 1 needs special equipment such as a photolithography-etching machine or a laser beam machine that operates in three dimensions. In addition, it has a problem that processable forms for etching are restricted.

The method disclosed in Patent Document 2 also needs to equip a mask which is preliminary molded in a three-dimensional form. As in the case of the method of Patent Document 1, it is not easy to conduct in technical and economic aspects.

The method disclosed in Patent Document 3 has a problem of deterioration of a circuit pattern at the time of molding. According to a usual molding method, a resin substrate is formed at high temperature and high pressure, and at that time, a circuit pattern would be peeled off and/or disconnected.

According to the method of pattern printing on a substrate using a plating catalyst ink containing a binder resin, a pattern layer containing catalyst solidified by the resin is formed on a substrate with above a certain level of thickness. In the subsequent three-dimensional molding process, therefore, the pattern layer on the substrate cannot follow transformation of the substrate at the time of molding, which might cause such troubles as disconnection caused by crack and/or peel-off. It might give rise to deposition failure in plating.

The present invention is to solve the above-described problems to provide a process for producing a three-dimensional conductive pattern structure in a simple way without need of any special apparatus, said structure having a conductive pattern formed thereon that exhibits excellent adhesiveness with no peel-off and disconnection. In addition, the present invention provides a material for three-dimensional molding and a process for producing the same, which can be suitably used for producing said three-dimensional conductive pattern structure.

Furthermore, the present invention provides a process for producing a three-dimensional structure for electroless plating on which a conductive pattern that exhibits excellent adhesiveness with no peel-off and disconnection can be formed.

### Means for Solving the Problems

That is, the present invention provides processes and the like shown as follows:

(1) A process for producing a three-dimensional conductive pattern structure having a conductive pattern formed on the surface of a three-dimensional structure, which comprises the following steps a)-d):
a) a modified-pattern forming step wherein a material for three-dimensional molding having a polyimide resin surface in at least a part thereof is subjected to pattern printing on said polyimide resin surface using a modifier to produce a material for three-dimensional molding on which a modified-pattern with cloven imide rings is formed,
b) a plating-catalytic-active pattern forming step wherein, on the pattern-formed place of said material for three-dimensional molding on which a modified-pattern is formed which is obtained by the step a), metal ions having plating catalytic activity are adsorbed, and subsequently said metal ions are reduced to produce a material for three-dimensional molding on which a pattern having plating catalytic activity is formed,
c) a three-dimensional molding step wherein said material for three-dimensional molding on which a pattern having plating catalytic activity is formed which is obtained by the step b) is three-dimensionally molded to produce a three-dimensional structure on which a pattern having plating catalytic activity is formed, and
d) an electroless plating step wherein said three-dimensional structure on which a pattern having plating catalytic activity is formed which is obtained by the step c) is subjected to electroless plating to form a conductive pattern to produce a three-dimensional conductive pattern structure.
(2) The process for producing a three-dimensional conductive pattern structure according to (1), wherein electrolytic plating is further carried out after electroless plating in said step d).
(3) The process for producing a three-dimensional conductive pattern structure according to (1), wherein said material for three-dimensional molding having a polyimide resin surface in at least apart thereof is a synthetic resin film or sheet having the thickness of 10-2000 μm.
(4) The process for producing a three-dimensional conductive pattern structure according to (1), wherein, in said material for three-dimensional molding on which a pattern having plating catalytic activity is formed which is obtained by the step b), the pattern having plating catalytic activity is formed over a range from the polyimide resin surface to a position having a depth from said surface of 20 nm or more.
(5) The process for producing a three-dimensional conductive pattern structure according to (1), wherein said metal ions having plating catalytic activity are palladium ions.
(6) The process for producing a three-dimensional conductive pattern structure according to (1), wherein said three-dimensional molding in the step c) is selected from the group consisting of vacuum molding, air-pressure molding, press molding and film insert molding.
(7) The process for producing a three-dimensional conductive pattern structure according to (1), wherein said modifier comprises alkaline components and organic solvents without comprising binder components.
(8) A material for three-dimensional molding having a polyimide resin surface in at least a part thereof, wherein a pattern having plating catalytic activity is formed on said polyimide resin surface, said pattern being made of a metal complex salt formed of carboxyl groups derived from polyimide and metal having plating catalytic activity.
(9) The material for three-dimensional molding according to (8), wherein said pattern having plating catalytic activity is formed over a range from the polyimide resin surface to a position having a depth from said surface of 20 nm or more.
(10) The material for three-dimensional molding according to (8), wherein said material for three-dimensional molding is a material for molding selected from the group consisting of vacuum molding, air-pressure molding, press molding and film insert molding.
(11) The material for three-dimensional molding according to (8), which is a synthetic resin film or sheet having the thickness of 10-2000 μm.
(12) A process for producing a material for three-dimensional molding having a polyimide resin surface in at least apart thereof wherein a pattern having plating catalytic activity is formed on said polyimide resin surface, which comprises the following steps a) and b):
a) a modified-pattern forming step wherein a material for three-dimensional molding having a polyimide resin surface in at least a part thereof is subjected to pattern printing on said polyimide resin surface using a modifier to produce a material for three-dimensional molding on which a modified-pattern with cloven imide rings is formed, and
b) a plating-catalytic-active pattern forming step wherein, on the pattern-forming place of said material for three-dimensional molding on which a modified-pattern is formed which is obtained by the step a), metal ions having plating catalytic activity are adsorbed, and subsequently said metal ions are reduced to produce a material for three-dimensional molding on which a pattern having plating catalytic activity is formed.
(13) A three-dimensional structure for electroless plating having a polyimide resin surface in at least a part thereof wherein a pattern having plating catalytic activity is formed on said polyimide resin surface, said pattern being made of a metal complex salt formed of carboxyl groups derived from polyimide and metal having plating catalytic activity.
(14) The three-dimensional structure for electroless plating according to (13), wherein said pattern having plating catalytic activity is formed over a range from the polyimide resin surface to a position having a depth from said surface of 20 nm or more.
(15) A process for producing a three-dimensional structure for electroless plating having a polyimide resin surface in at least a part thereof wherein a pattern having plating catalytic activity is formed on said polyimide resin surface, which comprises the following steps a)-c):
a) a modified-pattern forming step wherein a material for three-dimensional molding having a polyimide resin surface in at least a part thereof is subjected to pattern printing of an arbitrary pattern on said polyimide resin surface using a modifier comprising alkaline components to produce a material for three-dimensional molding on which a modified-pattern with cloven imide rings is formed,
b) a plating-catalytic-active pattern forming step wherein; on the pattern-formed place of said material for three-dimensional molding on which a modified-pattern is formed which is obtained by the step a), metal ions having plating catalytic activity are adsorbed to carboxyl groups generated by cleaving of imide rings of polyimide, and subsequently said metal ions are reduced to produce a material for three-dimensional molding on which a pattern having plating catalytic activity is formed, and
c) a three-dimensional molding step wherein said material for three-dimensional molding on which a pattern having plating catalytic activity is formed which is obtained by the step b) is three-dimensionally molded to produce a three-dimensional structure on which a pattern having plating catalytic activity is formed.
(16) The process for producing a three-dimensional structure for electroless plating according to (15), wherein said three-dimensional molding is selected from the group consisting of vacuum molding, air-pressure molding, press molding and film insert molding.

### Effect of the Invention

The material for three-dimensional molding of the present invention on which a pattern having plating catalytic activity is formed is obtained by printing a pattern using a modifier, and subsequently adsorbing plating catalytic metal ions thereon and reducing them. Unlike the method of forming a pattern by adhering plating catalyst ink containing binder components on the surface of a material, according to the present invention, catalytic metals are adsorbed in the vicinity of the surface of a material which is chemically modified. Therefore, the pattern is nearly homogeneous with the material, and since it shows a similar behavior to the material at the time of three-dimensionally molding even under conditions wherein severe loads such as high temperature, pressure and tension are applied, troubles such as peel-off and disconnection do not occur.

In addition, the pattern shows uniform plating catalytic activity. Therefore, by subjecting the material to three-dimensional molding, a three-dimensional structure for electroless plating having uniform plating catalytic activity can be obtained.

According to the process for producing a three-dimensional conductive pattern structure of the present invention, the material for three-dimensional molding having superior performance as described above is three-dimensionally molded and is subsequently subjected to electroless plating. Therefore, a three-dimensional conductive pattern structure on which a conductive pattern which exhibits excellent adhesiveness and uniformity with no peel-off and disconnection is formed can be obtained.

### BRIEF DESCRIPTION OF DRAWINGS

FIG. 1 shows a flow diagram of the process for producing the three-dimensional conductive pattern structure of the present invention.

FIG. 2 shows a schema of the three-dimensional structure which is obtained by three-dimensionally molding using the material for three-dimensional molding of the present invention.

### EXPLANATION OF REFERENCE LETTERS

1: Polyimide resin surface site
2: Pattern having plating catalytic activity

### MODES FOR CARRYING OUT THE INVENTION

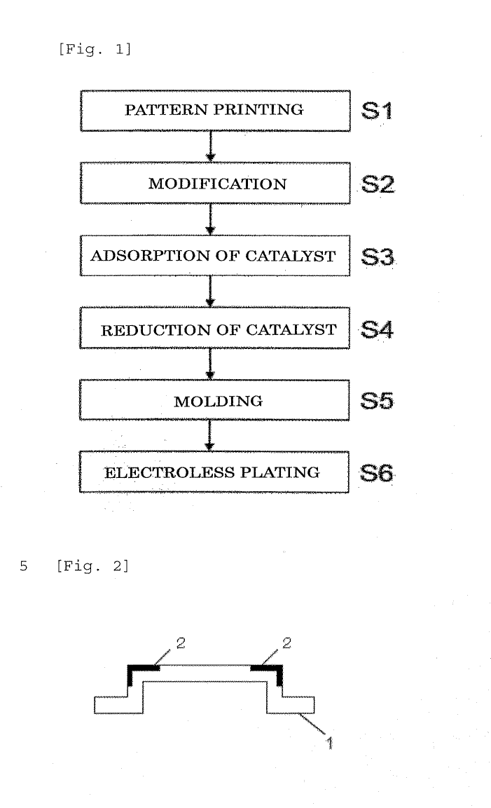

The process for producing the three-dimensional conductive pattern structure of the present invention will be described in more detail based on FIG. 1.

According to the process of the present invention, an arbitrary pattern is formed on the polyimide resin surface using a modifier. By the modifier, imide rings are cloven in the vicinity of the surface of the polyimide resin to form a modified-pattern (a modified-pattern forming step; S1-S2 in FIG. 1).

Subsequently, metal ions are adsorbed to the pattern-formed place wherein the modified-pattern is formed, and then the metal ions are reduced to produce a material for three-dimensional molding on which a pattern having plating catalytic activity is formed (a plating-catalytic-active pattern forming step; S3-S4). Then, said material for three-dimensional molding is subjected to three-dimensional molding (a three-dimensional molding step; S5). The three-dimensional structure thus obtained is subjected to electroless plating (an electroless plating step; S6).

### (1) Modified-Pattern Forming Step a):

In the modified-pattern forming step a) of the present invention, an arbitrary pattern capable of forming an intended conductive pattern is printed on the polyimide resin surface of a material for three-dimensional molding having a polyimide resin surface in at least a part thereof, using a modifier comprising alkaline components, to produce a material for three-dimensional molding on which a pattern made of a modifier, i.e. a place wherein a modifier is applied, is formed (see S1 in FIG. 1). Thereby, the polyimide resin surface is modified in the form of an arbitrary pattern capable of forming an intended conductive pattern.

The alkaline components comprised in the modifier can cleave the imide rings on the polyimide resin surface in the presence of water to generate carboxyl groups, that is, to make modification (see S2 in FIG. 1). When the modifier contains water, cleavage of the imide rings occurs by standing for a certain period of time after forming the pattern made of the modifier. When the modifier does not contain water, modification can be achieved by bringing into contact with water after forming a pattern made of the modifier. Examples of the methods for contacting with water include immersing in water, spraying water by a sprayer and steam spraying, but are not particularly limited.

### i) Material for Three-Dimensional Molding:

The material for three-dimensional molding to be used in the present invention is not particularly limited as long as it is a material capable of three-dimensional molding which has a surface made of a polyimide resin in at least a part thereof. Examples of the methods for three-dimensional molding include vacuum molding, air-pressure molding, press molding and film insert molding, but are not particularly limited. Vacuum molding and press molding are preferable.

Examples of such materials for three-dimensional molding include a synthetic resin film and a synthetic resin sheet which are commonly used for the above-described three-dimensional moldings. In particular, examples of such materials include a film or sheet for three-dimensional molding made of a polyimide resin and in addition, a composite material wherein a polyimide resin is coated or laminated on the surface of a film or sheet made of a synthetic resin other than a polyimide resin which can be used for three-dimensional molding.

Examples of the films or sheets capable of three-dimensional molding which are made of synthetic resins other than a polyimide resin include films or sheets made of polyester such as polyethylene terephthalate and polybutylene terephthalate, nylon, polyethylene, polypropylene, polystyrene, polycarbonate or polyacrylonitrile.

The thickness of the material for three-dimensional molding of the present invention is not particularly limited. However, it is preferable to have the thickness of 10-2000 μm, more preferably 50-1000 μm as the suitable thickness for three-dimensional molding.

The polyimide resin has imide rings in its molecular structure and they can be cloven to generate carboxy groups by treating with a suitable modifier. Commercially available products can be used as a polyimide resin of the present invention. Examples of the commercially available polyimide resins include a brand name “Kapton” manufactured by DuPont, a brand name “UPILEX” manufactured by Ube Industries, Ltd., and a brand name “APICAL” manufactured by Kaneka Corporation.

### ii) Modifier:

The modifier to be used in the present invention normally comprises alkaline components and solvents, which is used for cleaving imide rings on the polyimide resin surface by said alkaline components. Both organic compounds and inorganic compounds can be used as the alkaline components. Examples of the organic compounds include quaternary ammonium hydroxide salts such as tetramethyl ammonium hydroxide (TMAH), tetraethyl ammonium hydroxide (TEAH), tetrapropyl ammonium hydroxide (TPAH) and tetrabuthyl ammonium hydroxide (TBAH). Examples of the inorganic compounds include sodium hydroxide, potassium hydroxide, magnesium hydroxide and calcium hydroxide. Among them, it is preferable to use tetramethyl ammonium hydroxide (TMAH) or tetrabuthyl ammonium hydroxide (TBAH) as the organic compounds and sodium hydroxide or potassium hydroxide as the inorganic compounds because of their availability and dissolution stability in solvents.

The mixing ratio of the alkaline components based on the total amount of the modifier is preferably 0.1-10% by weight, more preferably 1-5% by weight in terms of KOH. By adjusting the ratio of the alkaline components within this range, sufficient modification of the polyimide resin surface can be achieved without damaging to the printer.

KOH conversion value of the alkaline components can be obtained according to the following mathematical formula:

[Alkaline Component Ratio in terms of KOH](% by weight)=[Alkaline Component Ratio](% by weight)×[(Molecular Weight of KOH: 56.12)/(Molecular Weight of Alkaline Component)] (Mathematical Formula)

It is preferable to use an organic solvent as the solvent to be used for the modifier of the present invention. Examples of the preferable organic solvents include alcohols, more preferably alcohols selected from the group consisting of hydrocarbon-based alcohols, alkylene glycols and glycol ethers.

Examples of hydrocarbon-based alcohols include alcohols derived from non-cyclic saturated hydrocarbon, preferably alcohols derived from non-cyclic saturated hydrocarbon having 5-10 carbon atoms, more preferably primary alcohols having 5-9 carbon atoms. In particular, examples thereof include isomers of pentanol having 5 carbon atoms and hexanol having 6 carbon atoms having a boiling point of 120° C. or higher. Examples of such hydrocarbon-based alcohols include 1-pentanol having a boiling point of 138° C., 1-hexanol having a boiling point of 158° C. and 1-octanol having a boiling point of 195° C.

Examples of alkylene glycols include diol-type solvents such as ethylene glycol, diethylene glycol, triethylene glycol, propylene glycol, dipropylene glycol and 1,3-butylene glycol.

Examples of glycol ethers include ethylene oxide (E.O.) based solvents such as ethylene glycol monobutyl ether, diethylene glycol monomethyl ether, diethylene glycol monoethyl ether and diethylene glycol monobutyl ether; and propylene oxide (P.O.) based solvents such as propylene glycol monomethyl ether, propylene glycol monobutyl ether and dipropylene glycol monomethyl ether.

Among them, it is preferable to use a compound having a sufficiently high boiling point in terms of printability, such as ethylene glycol, diethylene glycol, diethylene glycol monobutyl ether and dipropylene glycol monomethyl ether.

Two or more of these solvents can be mixed with each other.

The content of the organic solvent based on the total amount of the modifier of the present invention is preferably 30-99.9% by weight, more preferably 50-99% by weight, most preferably 80-99% by weight. By adjusting the content of the organic solvent within this range, suitable printability can be given to the modifier.

Besides the above-described alkaline components and solvents, the modifier can contain optional components such as fillers, thixotropic agents, water-soluble polymer compounds and thickening agents. The content of water-soluble polymer compounds is preferably not more than 20% by weight. The water-soluble polymer compound enables to keep the alkaline components on the polyimide resin surface until the modification is completed. After completion of the modification, it can easily be removed by means of water washing or the like with the extra alkaline components.

iii) Printing

Examples of the methods for printing an arbitrary pattern using the above-described modifier include inkjet printing, screen printing, gravure printing, and gravure offset printing. While any of these methods can be employed, inkjet printing and gravure offset printing are preferable.

After printing, it is preferable to remove the organic solvent in the modifier. As the methods for removing the organic solvent, various methods for drying such as drying under heating, drying in a warm air flow and drying under reduced pressure can be employed, and are not particularly limited. Among them, drying under heating is preferable. By removing the organic solvent, the modifier printed in a pattern shape loses fluidity, whereby the pattern shape to be modified on the polyimide resin surface is determined. In the case of removing the organic solvent by drying under heating, it is preferable to carry out a heat treatment at preferably 40-200° C., more preferably 100-180° C., for 1-120 minutes, more preferably 1-60 minutes.

### iv) Modification

After the pattern made of the modifier is formed on the polyimide resin surface, modification reaction is carried out at the pattern-formed place wherein said pattern is formed. By the modification reaction, imide rings of the polyimide resin at the pattern-formed place are cloven to generate carboxyl groups (see S2 in FIG. 1).

In the case that the modifier contains water, it is not particularly necessary to carry out a special treatment for modification reaction. It is only necessary to allow the material for three-dimensional molding on which the pattern made of the modifier is formed to stand still for a certain period of time.

In the case that the modifier does not contain water, the material for three-dimensional molding on which the pattern made of the modifier is formed can be brought into contact with water. Examples of the methods for contacting with water include immersing in water, spraying water by a sprayer, contacting fabrics and/or sponges moistened with water and contacting steam, but are not particularly limited.

After modification, the extra modifier can be removed by washing so as not to remain on the modified place of the polyimide resin surface. On the polyimide resin surface, accordingly, the place wherein imide rings of polyimide are cloven by the modification reaction to generate carboxyl groups is formed in a pattern. That is, a material for three-dimensional molding having a modified place which is formed in a pattern (=modified pattern) is obtained.

In terms of plating adhesiveness and uniform plating selectivity, it is desirable to prevent the modifier from remaining at the time of applying catalyst to the modified place and carrying out plating deposition. Examples of preferable solvents for washing include water. As a method for washing with water, known washing methods can be employed. Examples of the known washing methods include ultrasonic washing, spray and/or shower washing, brush washing, dip washing and two-fluid washing. These washing methods can be selected appropriately and are not particularly limited.

### (2) Plating-Catalytic-Active Pattern Forming Step b)

In the plating-catalytic-active pattern forming step b) of the present invention, metal ions of metals having plating catalytic activity are adsorbed on the pattern-formed place of the material for three-dimensional molding on which a modified pattern is formed which is obtained by the step a), and subsequently said metal ions are reduced. In particular, metal ions of metals having plating catalytic activity are adsorbed to carboxyl groups which are generated by cleaving imide rings of the polyimide resin by the modifier (see S3 in FIG. 1), and then said metal ions are reduced ((see S4 in FIG. 1). Metal ions are coordinated by adsorption with carboxyl groups generated on the polyamide resin surface to form metal complex salts, and said metal complex salts are reduced. Accordingly, the material for three-dimensional molding on which a pattern having plating catalytic activity is formed can be produced.

Examples of metals having plating catalytic activity include copper, nickel, silver, tin, rhodium, palladium, gold and platinum. Among them, it is preferable to use palladium which has high plating catalytic activity.

Examples of the compounds capable of generating palladium ions include palladium chloride, palladium bromide, palladium acetate, palladium sulfate, palladium nitrate, palladium acetylacetonate and palladium oxide. Among them, palladium chloride which is widely used as a common catalyst is suitably used in terms of relatively easy availability.

Examples of the methods for adsorbing metal ions to the polyimide resin surface of the material for three-dimensional molding include a method wherein the polyimide resin surface of the material for three-dimensional molding on which the above-described imide rings are cloven is brought into contact with a solution containing said metal ions.

Examples of the methods for contacting the material for three-dimensional molding with said solution containing metal ions include immersing the material for three-dimensional molding into the solution containing metal ions and spraying the solution containing metal ions to the material for three-dimensional molding.

Solvents used for the solution containing metal ions are not particularly limited, but water is preferable.

The metal ion concentration of the solution containing metal ions is preferably 0.01 mM-50 mM, more preferably 0.05 mM-20 mM, further preferably 0.05 mM-10 mM, most preferably 0.08 mM-0.9 mM.

The reaction temperature at the time of contacting the material for three-dimensional molding with the solution containing metal ions is 10° C.-80° C., preferably 30° C.-50° C. The contacting time of the solution containing metal ions is preferably 10 sec-800 sec, more preferably 60 sec-500 sec.

After contacting the solution containing metal ions, the material for three-dimensional molding is preferably subjected to washing with water to remove metal ions which are non-specifically adhered. As a method for washing with water, known washing methods can be employed. Examples thereof include ultrasonic washing, spray and/or shower washing, brush washing, dip washing and two-fluid washing. These washing methods can be selected appropriately and are not particularly limited.

The preferable method for reducing is to contact the material for three-dimensional molding on which metal ions are adsorbed with an acidic treatment liquid containing a reducing agent. Examples of the reducing agents used for the acidic treatment liquid containing a reducing agent include dimethylamineborane, sodium hypophosphite, hydrazine, diethyl amine and ascorbic acid. Among them, dimethylamineborane is most preferable in terms of usability in a more acidic region and excellent reducing power.

The concentration of the reducing agent in the acidic treatment liquid containing a reducing agent is preferably 1 mM-100 mM, more preferably 10 mM-30 mM. The solvent to be used for the acidic treatment liquid containing a reducing agent of the present invention is not particularly limited. It is preferable to use water as the solvent.

The pH of the acidic treatment liquid containing a reducing agent of the present invention is preferably 6 or less, more preferably 2-6, further preferably 3-5.9.

The acidic treatment liquid containing a reducing agent of the present invention can be prepared by dissolving said reducing agent into an acidic buffer agent accordingly in order to maintain an appropriate pH range. Known buffer agents can be used as said acidic buffer agent. Examples thereof include a 0.1M citrate buffer solution and an acetate buffer solution.

By using the acidic treatment liquid containing a reducing agent, the solution containing metal ions having a low concentration of metal ions can be used, and reduction of the metal complex salts can be carried out more effectively.

The contact time of the material for three-dimensional molding with the acidic treatment liquid containing a reducing agent is preferably 60 seconds to 600 seconds, more preferably 180 seconds to 300 seconds. The contact temperature is preferably 10° C. to 80° C., more preferably 30° C. to 50° C.

After contacting with the acidic treatment liquid containing a reducing agent, the material for three-dimensional molding is subjected to washing with water to remove the solution containing a reducing agent nonspecifically adhered.

After completion of the reduction treatment, the material is subjected to washing and drying if necessary to obtain a material for three-dimensional molding on which a pattern having plating catalytic activity is formed. The material for three-dimensional molding on which a pattern having plating catalytic activity is formed thus obtained has metal which has plating catalytic activity, or which can be a plating catalyst, adsorbed on the polyimide resin surface which is modified (see 1 in FIG. 2).

In other words, the material for three-dimensional molding of the present invention has a polyimide resin surface in at least a part thereof, wherein a pattern having plating catalytic activity is formed on said polyimide resin surface, said pattern being made of a metal complex salt formed of carboxyl groups derived from polyimide and metal having plating catalytic activity. According to the material for three-dimensional molding of the present invention, even under thermal and/or physical treatments at the time of molding, elimination of metal and/or damage of the pattern having plating catalytic activity (see 2 in FIG. 2) can be prevented.

Compared with the conventional materials for three-dimensional molding wherein a pattern is formed by printing or coating directly thereon using plating catalyst ink containing metal having plating catalytic activity and a binder component, the material for three-dimensional molding of the present invention exhibits excellent performances such that, even after three-dimensionally molding, elimination and/or deterioration of metal having plating catalytic activity can be prevented and the pattern has high adhesiveness and stability. In addition, it exhibits uniform plating catalytic activity.

The pattern having plating catalytic activity is preferably formed over a range from the polyimide resin surface to a position having a depth from said surface of 20 nm or more. More preferably, it is formed over a range from the polyimide resin surface to a position having a depth from said surface of 100 nm or more. When the depth at which the pattern having plating catalytic activity is formed is in the above-described range, stability of the pattern after three-dimensionally molding can be even higher and adhesiveness of metal films formed by electroless plating can also be higher.

The depth at which the pattern having plating catalytic activity is formed can be obtained by measuring the distribution of metal having plating catalytic activity by means of elemental analysis using TEM (=Transmission Electron Microscope).

### (3) Three-Dimensional Molding Step c):

In the three-dimensional molding step c), the material for three-dimensional molding on which a pattern having plating catalytic activity is formed which is obtained by the above step b) is three-dimensionally molded to produce a three-dimensional structure having a stereoscopic structure (see S5 in FIG. 1).

While the method of three-dimensionally molding is not particularly limited, examples thereof include vacuum molding or vacuum thermoforming, air-pressure molding, press molding and film insert molding. It is preferable to employ vacuum molding (or vacuum thermoforming) and press molding. In particular, vacuum molding is most preferable in terms of low molding cost and advantages for large size production and/or small lot production.

Preferable conditions for vacuum molding (or vacuum thermoforming) are such that the molding temperature of 150° C. to 360° C., the molding pressures of 1.3×10 Pa to 6.7×10³ Pa and the molding time of 10 sec to 60 sec.

Preferable conditions for press molding are such that the molding temperature of 150° C. to 360° C., the molding pressures of 5×10⁴ Pa to 5×10⁵ Pa and the molding time of 10 sec to 60 sec.

On the polyimide resin part of the surface of the three-dimensional structure thus obtained, a pattern having plating catalytic activity is formed, said pattern being containing a reduced product of a metal salt formed of carboxyl groups derived from polyimide and metal ion which has plating catalytic activity.

Compared with three-dimensional structures obtained by molding conventional materials for three-dimensional molding wherein a pattern is formed by printing or coating directly thereon using plating catalyst ink containing metal having plating catalytic activity and a binder component, the three-dimensional structure of the present invention which is obtained by molding the material for three-dimensional molding of the present invention exhibits excellent performances such that elimination and/or deterioration of metal having plating catalytic activity can be prevented, and damage of the pattern having plating catalytic activity (see 2 in FIG. 2) can also be prevented and the pattern has high adhesiveness and stability. In addition, it exhibits uniform plating catalytic activity.

While the depth at which the pattern having plating catalytic activity is formed on said three-dimensional structure is not particularly limited, it is preferably formed over a range from the polyimide resin surface to a position having a depth from said surface of 20 nm or more. More preferably, it is formed over a range from the polyimide resin surface to a position having a depth from said surface of 100 nm or more. When the depth at which the pattern having plating catalytic activity is formed is in the above-described range, stability of the pattern can be even higher, and plating deposition performance and adhesiveness of metal films are excellent. Therefore, it is suitable for electroless plating treatment.

While the upper limit of the depth at which the pattern having plating catalytic activity is formed is not particularly limited, the depth is preferably up to 200 nm in light of a significant influence on the deterioration of strength of the polyimide resin by modification.

### (4) Conductive Pattern Forming Step d):

In the conductive pattern forming step (or the electroless plating step) d) of the present invention, the three-dimensional structure on which a pattern having plating catalytic activity is formed which is obtained by the three-dimensional molding step c) is subjected to electroless plating to form a conductive pattern to produce a three-dimensional conductive pattern structure (see S6 in FIG. 1). That is, a metal film is formed by electroless plating on the pattern having plating catalytic activity which is formed on the polyimide resin surface of said three-dimensional structure.

As the method for electroless plating in the present invention, any known electroless plating methods can be employed. Examples of metals for electroless plating include at least one selected from the group consisting of copper, nickel, tin and silver and alloys thereof such as an alloy of copper and tin. Among them, copper and nickel are preferable, and nickel is particularly preferable. By this metal plating process, an electroless plating film having high conductivity (or a conductive pattern or a conductive metal layer) can be formed on the pattern having plating catalytic activity which is formed on the three-dimensional structure.

As for electroless plating, existing plating bathes can be used and the above-described three-dimensional structure can be immersed into said plating bath. The reaction time and the temperature for plating can be adjusted properly depending on the plating film thickness.

The film thickness of the electroless plating film (or the conductive pattern or the conductive metal layer) of the present invention is preferably 10 nm-300 nm, more preferably 20 nm-200 nm. The electroless plating film functions as a seed layer which can improve adhesiveness with the three-dimensional structure, and its effect is exhibited more successfully within the above range of the film thickness.

After forming an electroless plating film, the three-dimensional structure can be washed with water if necessary to remove the plating solution non-specifically adhered.

After forming an electroless plating film (or a conductive pattern or a conductive metal layer) by electroless plating, in addition, a plurality of metal layers can be laminated by further carrying out electroless plating using another kind of metal. Or, metal layers can be laminated on the electroless plating film by further carrying out electrolytic plating. As for the method for electrolytic plating, know methods can be employed. Examples of metals for electrolytic plating include copper, nickel, silver, zinc, tin and gold. Among them, copper is most preferable.

According to the present invention, a three-dimensional conductive pattern structure on which a conductive pattern made of a uniform metal film, preferably copper film, having the film thickness of preferably 0.5 μm-10 μm, more preferably 1 μm-6 μm and the line width of preferably 20 μm-600 μm, more preferably 30 μm-300 μm is formed can be obtained.

The three-dimensional conductive pattern structure thus obtained can be suitably used for various uses such as three-dimensional circuit boards, reflectors, antennas, electromagnetic shielding materials, switches and sensors.

### EXAMPLES

### Example 1

### Production of a Material for Three-Dimensional Molding on which a Pattern Having Plating Catalytic Activity is Formed

A polyimide resin film having the thickness of 125 μm, the brand name “Kapton JP” manufactured by DU PONT-TORAY CO., LTD., 21 cm×25 cm, was used for the material for three-dimensional molding having a polyimide resin surface of the present invention. A pattern made of a modifier was printed on said material by using an inkjet printer. The modifier used was a solution containing 2.5% by weight concentration of potassium hydroxide (KOH) as an alkaline agent in dipropylene glycol monomethyl ether as a solvent.

By the above-mentioned process, a printed pattern which is intended to derive a conductive pattern having the line width of 500 μm was formed on the polyimide resin surface of the material for three-dimensional molding. Subsequently, the polyimide resin film on which a pattern made of the modifier was printed was heated at 120° C. for 20 minutes, and then was immersed into water. After that, it was washed with water to remove the modifier.

Subsequently, the polyimide resin film was immersed into a 0.1 mM palladium chloride solution at 40° C. for 300 seconds to adsorb palladium ions to carboxyl groups which had been generated by the modifier. Then, the polyimide resin film was taken out of the solution and was subjected to washing with water to remove palladium ions non-specifically adhered.

Subsequently, said polyimide resin film was immersed into an acidic treatment liquid containing a reducing agent having pH 6 at 40° C. for 180 seconds to reduce palladium salts on the polyimide resin film, said acidic treatment liquid being a 0.1M citrate buffer solution containing 20 mM concentration of dimethylamineborane. Then, the polyimide resin film was taken out of the acidic treatment liquid containing a reducing agent and was washed with water to remove the reducing agent which was adhered non-specifically. Then, it was dried to obtain a material for three-dimensional molding on which a pattern having plating catalytic activity was formed.

### (Production of a Three-Dimensional Conductive Pattern Structure)

The material for three-dimensional molding thus obtained on which a pattern having plating catalytic activity was formed was subjected to vacuum thermoforming under the conditions of the temperature at 300° C., the pressure of 5×10 Pa and the molding time of 30 seconds to obtain a three-dimensional structure. The shape of said three-dimensional structure thus obtained was shown in FIG. 2.

Subsequently, the three-dimensional structure thus obtained was subjected to electroless plating by immersing into an electroless nickel plating bath, the brand name “ES-500”, manufactured by EBARA-UDYLITE CO., LTD., at 40° C. for 1 minute. By this treatment, a nickel plating film having the film thickness of 100 nm was formed selectively only on a pattern wherein palladium had been adsorbed in the above-described process. After that, the excess nickel plating solution being non-specifically adhered was removed by washing with flowing water at room temperature.

Then, electrolytic plating was carried out using a copper sulfate plating bath under the current density of 4 A/dm² for 5 minutes to form a copper plating film having the film thickness of 5 μm. The above-mentioned copper sulfate plating bath contained 120 g/l of copper sulfate, 150 g/l of sulfuric acid, 50 mg/l of chlorine ions and a brightening agent containing 10 ml/l of the brand name “Cu-Brite RF MU” and 1 ml/l of the brand name “Cu-Brite RFP-B”, both manufactured by EBARA-UDYLITE CO., LTD. By the above-described process, a three-dimensional conductive pattern structure on which a metal film pattern having the line width of 500 μm and the metal (copper) film thickness of 5 μm was obtained.

### Example 2

### Production of a Material for Three-Dimensional Molding on which a Pattern Having Plating Catalytic Activity is Formed

Liquid polyimide which was a N-methyl-2-pyrolidone solution containing 20% by weight of polyamic acid was coated on a PET resin film for molding having the film thickness of 100 μm, the brand name of “DIAFOIL”, manufactured by Mitsubishi Plastics, Inc., 21 cm×25 cm, by using a bar coater. Then, the PET resin film was subjected to drying by heating at 80° C. for 30 minutes to form a film having the thickness of 1.0 μm. Thereby, a material for three-dimensional molding which had a polyimide resin surface and was capable of three-dimensional molding was obtained.

Subsequently, pattern printing was carried out on the polyimide resin surface of the above-described material for three-dimensional molding in the same manner as Example 1 using the same modifier as used in Example 1. Then, after heating at 80° C. for 20 minutes, the material for three-dimensional molding was immersed into water. After that, the material for three-dimensional molding was washed with water to remove the modifier.

Subsequently, the material for three-dimensional molding was immersed into a 0.1 mM palladium chloride solution at 40° C. for 300 seconds to adsorb palladium ions to carboxyl groups which had been generated by the modifier. Then, the material for three-dimensional molding was taken out of the solution and was subjected to washing with water to remove palladium ions non-specifically adhered.

Subsequently, said material for three-dimensional molding was immersed into an acidic treatment liquid containing a reducing agent having pH 6 at 40° C. for 180 seconds to reduce palladium salts on the polyimide resin surface of the material for three-dimensional molding film, said acidic treatment liquid being a 0.1M citrate buffer solution containing 20 mM concentration of dimethylamineborane. Then, the material for three-dimensional molding was taken out of the acidic treatment liquid containing a reducing agent and was washed with water to remove the reducing agent which was adhered non-specifically. Then, it was dried to obtain a material for three-dimensional molding on which a pattern having plating catalytic activity was formed.

### (Production of a Three-Dimensional Conductive Pattern Structure)

The material for three-dimensional molding thus obtained on which a pattern having plating catalytic activity was formed was subjected to vacuum thermoforming under the conditions of the temperature at 300° C., the pressure of 5×10 Pa and the molding time of 30 seconds to obtain a three-dimensional structure. The shape of said three-dimensional structure thus obtained was shown in FIG. 2.

Subsequently, the three-dimensional structure thus obtained was subjected to electroless plating by immersing into an electroless nickel plating bath, the brand name “ES-500”, manufactured by EBARA-UDYLITE CO., LTD., at 40° C. for 1 minute. By this treatment, a nickel plating film having the film thickness of 100 nm was formed selectively only on a pattern wherein palladium had been adsorbed in the above-described process. After that, the excess nickel plating solution being non-specifically adhered was removed by washing with flowing water at room temperature.

Then, electrolytic plating was carried out using a copper sulfate plating bath under the current density of 4 A/dm² for 5 minutes to form a copper plating film having the film thickness of 5 μm. The above-mentioned copper sulfate plating bath contained 120 g/l of copper sulfate, 150 g/l of sulfuric acid, 50 mg/l of chlorine ions and a brightening agent containing 10 ml/l of the brand name “Cu-Brite RF MU” and 1 ml/l of the brand name “Cu-Brite RFP-B”, both manufactured by EBARA-UDYLITE CO., LTD. By the above process, a three-dimensional conductive pattern structure on which a metal film pattern having the line width of 500 μm and the metal (copper) film thickness of 5 μm was obtained.

### Comparative Example 1

### Production of a Material for Three-Dimensional Molding

A line pattern having the line width of 500 μm was printed on a polyimide resin film having the thickness of 125 μm, the brand name “Kapton JP”, manufactured by DU PONT-TORAY CO., LTD., 21 cm×25 cm, using palladium catalyst ink by an inkjet printer in the same manner as Example 1 to obtain a material for three-dimensional molding on which a pattern made of palladium catalyst ink was formed. The palladium catalyst ink used here was a styrene-based resin having ammonium ends containing metal palladium nanoparticles, the brand name “HYPERTECH MC-001”, manufactured by Nissanchemical Industries, Ltd.

### (Production of a Three-Dimensional Conductive Pattern Structure)

The material for three-dimensional molding on which a pattern made of palladium catalyst ink thus obtained was subjected to vacuum thermoforming in the same manner as Example 1 under the conditions of the temperature at 300° C., the pressure of 5×10 Pa and the molding time of 30 seconds to obtain a three-dimensional structure. The shape of said three-dimensional structure thus obtained was shown in FIG. 2.

Subsequently, the three-dimensional structure thus obtained was subjected to electroless plating by immersing into an electroless nickel plating bath, the brand name “ES-500”, manufactured by EBARA-UDYLITE CO., LTD., at 40° C. for 1 minute. By this treatment, a nickel plating film was formed on a pattern made of palladium catalyst ink. At the time of molding, the line pattern having the line width of 500 μm which had been formed by printing using palladium catalyst ink could not follow the transformation of the resin at the time of molding, which caused disconnection of the pattern. Deposition failure in plating occurred at the disconnected pattern portion. The results are shown in Table 1.

TABLE 1

| | | | Comparative |
|---|---|---|---|
| | Example 1 | Example 2 | Example 1 |
| Plating performance | No | No | Disconnection |
| on the pattern formed | Discon- | Discon- | occurred at |
| on the three-dimen- | nection | nection | the molded part |
| sional structure | | | caused by depo- |
| | | | sition failure. |
| Manufacturability | Possible | Possible | Impossible |
| of the three-dimen- | | | |
| sional conductive | | | |
| pattern structure | | | |

In Comparative Example 1 wherein a catalyst pattern was formed using plating catalyst ink containing a binder resin, a layer containing catalyst solidified by the resin was formed with above a certain level of thickness. This is considered to be the reason that the catalyst pattern could not follow the transformation of the molding material at the time of three-dimensional molding to cause disconnection of the pattern, and as a result, deposition failure in plating occurred.

### INDUSTRIAL APPLICABILITY

According to the present invention, a three-dimensional conductive pattern structure on which a conductive pattern that exhibits excellent adhesiveness with no peel-off or disconnection is formed can be produced by a simple way without need for any special apparatus. The three-dimensional conductive pattern structure of the present invention thus obtained can be suitably used for various uses such as three-dimensional circuit boards, reflectors, antennas, electromagnetic shielding materials, switches and sensors.

1. A process for producing a three-dimensional conductive pattern structure having a conductive pattern formed on the surface of a three-dimensional structure, which comprises the following steps a)-d):
a) a modified-pattern forming step wherein a material for three-dimensional molding having a polyimide resin surface in at least a part thereof is subjected to pattern printing on said polyimide resin surface using a modifier to produce a material for three-dimensional molding on which a modified-pattern with cloven imide rings is formed,
b) a plating-catalytic-active pattern forming step wherein, on the pattern-formed place of said material for three-dimensional molding on which a modified-pattern is formed which is obtained by the step a), metal ions having plating catalytic activity are adsorbed, and subsequently said metal ions are reduced to produce a material for three-dimensional molding on which a pattern having plating catalytic activity is formed,
c) a three-dimensional molding step wherein said material for three-dimensional molding on which a pattern having plating catalytic activity is formed which is obtained by the step b) is three-dimensionally molded to produce a three-dimensional structure on which a pattern having plating catalytic activity is formed, and
d) an electroless plating step wherein said three-dimensional structure on which a pattern having plating catalytic activity is formed which is obtained by the step c) is subjected to electroless plating to form a conductive pattern to produce a three-dimensional conductive pattern structure.

2. The process for producing a three-dimensional conductive pattern structure according to claim 1, wherein electrolytic plating is further carried out after electroless plating in said step d).

3. The process for producing a three-dimensional conductive pattern structure according to claim 1, wherein said material for three-dimensional molding having a polyimide resin surface in at least a part thereof is a synthetic resin film or sheet having the thickness of 10-2000 μm.

4. The process for producing a three-dimensional conductive pattern structure according to claim 1, wherein, in said material for three-dimensional molding on which a pattern having plating catalytic activity is formed which is obtained by the step b), the pattern having plating catalytic activity is formed over a range from the polyimide resin surface to a position having a depth from said surface of 20 nm or more.

5. The process for producing a three-dimensional conductive pattern structure according to claim 1, wherein said metal ions having plating catalytic activity are palladium ions.

6. The process for producing a three-dimensional conductive pattern structure according to claim 1, wherein said three-dimensional molding in the step c) is selected from the group consisting of vacuum molding, air-pressure molding, press molding and film insert molding.

7. The process for producing a three-dimensional conductive pattern structure according to claim 1, wherein said modifier comprises alkaline components and organic solvents without comprising binder components.

8. A material for three-dimensional molding having a polyimide resin surface in at least a part thereof, wherein a pattern having plating catalytic activity is formed on said polyimide resin surface, said pattern being made of a metal complex salt formed of carboxyl groups derived from polyimide and metal having plating catalytic activity.

9. The material for three-dimensional molding according to claim 8, wherein, said pattern having plating catalytic activity is formed over a range from the polyimide resin surface to a position having a depth from said surface of 20 nm or more.

10. The material for three-dimensional molding according to claim 8, wherein said material for three-dimensional molding is a material for molding selected from the group consisting of vacuum molding, air-pressure molding, press molding and film insert molding.

11. The material for three-dimensional molding according to claim 8, which is a synthetic resin film or sheet having the thickness of 10-2000 μm.

12. A process for producing a material for three-dimensional molding having a polyimide resin surface in at least apart thereof wherein a pattern having plating catalytic activity is formed on said polyimide resin surface, which comprises the following steps a) and b):
a) a modified-pattern forming step wherein a material for three-dimensional molding having a polyimide resin surface in at least a part thereof is subjected to pattern printing on said polyimide resin surface using a modifier to produce a material for three-dimensional molding on which a modified-pattern with cloven imide rings is formed, and
b) a plating-catalytic-active pattern forming step wherein, on the pattern-forming place of said material for three-dimensional molding on which a modified-pattern is formed which is obtained by the step a), metal ions having plating catalytic activity are adsorbed, and subsequently said metal ions are reduced to produce a material for three-dimensional molding on which a pattern having plating catalytic activity is formed.

13. A three-dimensional structure for electroless plating having a polyimide resin surface in at least apart thereof wherein a pattern having plating catalytic activity is formed on said polyimide resin surface, said pattern being made of a metal complex salt formed of carboxyl groups derived from polyimide and metal having plating catalytic activity.

14. The three-dimensional structure for electroless plating according to claim 13, wherein said pattern having plating catalytic activity is formed over a range from the polyimide resin surface to a position having a depth from said surface of 20 nm or more.

15. A process for producing a three-dimensional structure for electroless plating having a polyimide resin surface in at least a part thereof wherein a pattern having plating catalytic activity is formed on said polyimide resin surface, which comprises the following steps a)-c):
a) a modified-pattern forming step wherein a material for three-dimensional molding having a polyimide resin surface in at least a part thereof is subjected to pattern printing of an arbitrary pattern on said polyimide resin surface using a modifier comprising alkaline components to produce a material for three-dimensional molding on which a modified-pattern with cloven imide rings is formed,
b) a plating-catalytic-active pattern forming step wherein, on the pattern-formed place of said material for three-dimensional molding on which a modified-pattern is formed which is obtained by the step a), metal ions having plating catalytic activity are adsorbed to carboxyl groups generated by cleaving of imide rings of polyimide, and subsequently said metal ions are reduced to produce a material for three-dimensional molding on which a pattern having plating catalytic activity is formed, and
c) a three-dimensional molding step wherein said material for three-dimensional molding on which a pattern having plating catalytic activity is formed which is obtained by the step b) is three-dimensionally molded to produce a three-dimensional structure on which a pattern having plating catalytic activity is formed.

16. The process for producing a three-dimensional structure for electroless plating according to claim 15, wherein said three-dimensional molding is selected from the group consisting of vacuum molding, pressure molding, press molding and film insert molding.
